(19) United States
(12) Patent Application Publication
(10) Pub. No.: US 2025/0125141 A1
(43) Pub. Date: Apr. 17, 2025

(54) EPITAXIAL WAFER AND A METHOD FOR MANUFACTURING AN EPITAXIAL WAFER

(71) Applicant: SK SILTRON CO., LTD., Gumi-si (KR)

(72) Inventors: Gun Ho LEE, Gumi-si (KR); Byeong Ha KO, Gumi-si (KR); Doo Hyung MOON, Gumi-si (KR)

(21) Appl. No.: 18/902,655

(22) Filed: Sep. 30, 2024

(30) Foreign Application Priority Data
Oct. 12, 2023 (KR) 10-2023-0135809

(51) Int. Cl. H01L 21/02; C30B 25/18

(52) U.S. Cl. CPC H01L 21/02024; C30B 25/186; H01L 21/02016; H01L 21/02043; H01L 21/0262

(57) ABSTRACT

A method for manufacturing an epitaxial wafer may comprise polishing a back surface and a front surface of a wafer using a double-side polishing process, forming a protective film on the back surface of the polished wafer, forming an epi layer on the front surface of the wafer on which the protective film is formed to form an epitaxial wafer, and cleaning the epitaxial wafer.

### CROSS-REFERENCE TO RELATED APPLICATIONS

The present application claims the benefits of priority to Korean Patent Application No. 10-2023-0135809, filed on Oct. 12, 2023, in the Republic of Korea, the entire contents of which are hereby expressly incorporated by reference into the present application.

### BACKGROUND OF THE DISCLOSURE

### Field

The embodiment relates to an epitaxial wafer and a method for manufacturing an epitaxial wafer.

### Discussion of the Related Art

An epitaxial wafer is a substrate on which an epitaxial layer is formed on a wafer, and is widely used in the manufacture of a semiconductor device. That is, various semiconductor devices such as a microprocessor (MPU, MCU), a logic device (system IC, LCD IC), a flash memory, and a power semiconductor device are manufactured using an epitaxial wafer as a substrate.

Meanwhile, as shown in FIG. 1A, an epitaxial wafer 2 is frequently placed on a stage 1 for the manufacture of a semiconductor device. When the roughness of the back surface of the epitaxial wafer 2 is small, the epitaxial wafer 2 may slip, causing the epitaxial wafer 2 to be damaged or fall off the stage 1. In addition, when the epitaxial wafer 2 slips, as shown in FIG. 1A and FIG. 1B, there is a problem that particles 5 on the back surface of the epitaxial wafer 2 are transferred to the front surface, thereby contaminating the front surface of the epitaxial wafer 2.

Therefore, development of a technology capable of preventing slippage of the epitaxial wafer 2 is urgent.

### SUMMARY OF THE DISCLOSURE

An object of the embodiment is to solve the foregoing and other problems.

Another object of the embodiment is to provide an epitaxial wafer and a method for manufacturing an epitaxial wafer capable of preventing slippage.

Another object of the embodiment is to provide a method for manufacturing an epitaxial wafer capable of securing sufficient roughness and reducing the number of processes.

The technical problems of the embodiments are not limited to those described in this item and include those that can be understood through the description of the invention.

According to the first aspect of the embodiment to achieve the above or other objects, a method for manufacturing an epitaxial wafer, comprises: polishing front and back surfaces of a wafer using a double-side polishing process; forming a protective film on the back surface of the polished wafer; forming an epi layer on the front surface of the wafer on which the protective film is formed to form an epitaxial wafer; and cleaning the epitaxial wafer.

The forming of the protective film may comprise forming the protective film on a side surface of the polished wafer.

The front and back surfaces of the polished wafer may have a first roughness and a second roughness, respectively, and the second roughness may be equal to or greater than the first roughness.

The front and back surfaces of the formed epitaxial wafer may have a third roughness and a fourth roughness, respectively, and the third roughness may be smaller than the first roughness, and the fourth roughness may be equal to the second roughness.

The cleaning of the epitaxial wafer may comprise removing the protective film.

The front and back surfaces of the epitaxial wafer from which the protective film has been removed may have a fifth roughness and a sixth roughness, respectively, and the sixth roughness may be the same as the second roughness.

The protective film may comprise an oxide film.

The oxide film may be formed using a low-temperature oxidation process.

According to the second aspect of the embodiment to achieve the above or other objects, the epitaxial wafer is manufactured by the manufacturing method.

The effects of the epitaxial wafer and the method for manufacturing the epitaxial wafer according to the embodiment are described as follows.

According to at least one of the embodiments, a protective film may be formed on the back surface of the wafer before performing the EPI process, and the protective film may be removed after performing the EPI process. Since the roughness of the back surface of the wafer on which the DSP process is performed is maintained, the epitaxial wafer does not slip even when the epitaxial wafer is placed on the stage for the manufacture of semiconductor devices. Accordingly, not only is the epitaxial wafer prevented from falling or being damaged due to slipping of the epitaxial wafer, but particles on the back surface of the epitaxial wafer are prevented from being transferred to the front surface and contaminating the front surface of the epitaxial wafer.

Additional scope of applicability of the embodiments will become apparent from the detailed description that follows. However, since various changes and modifications within the idea and scope of the embodiments may be clearly understood by those skilled in the art, the detailed description and specific embodiments, such as preferred embodiments, should be understood as being given by way of example only.

### BRIEF DESCRIPTION OF THE DRAWINGS

FIG. 1A shows an epitaxial wafer sliding on a stage.

FIG. 1B shows an epitaxial wafer whose front surface is contaminated by particles.

FIG. 2 illustrates a method for manufacturing an epitaxial wafer according to a comparative example.

FIG. 3 illustrates a method for manufacturing an epitaxial wafer according to an embodiment.

FIG. 4 is a power spectrum density (PSD) graph showing the roughness in each of the comparative example and the embodiment.

FIG. 5 is a topology showing the roughness in each of the comparative example and the embodiment.

FIG. 6 (i.e., FIG. 6A and FIG. 6B) is a topology showing the roughness according to the location in each of the comparative example and the embodiment.

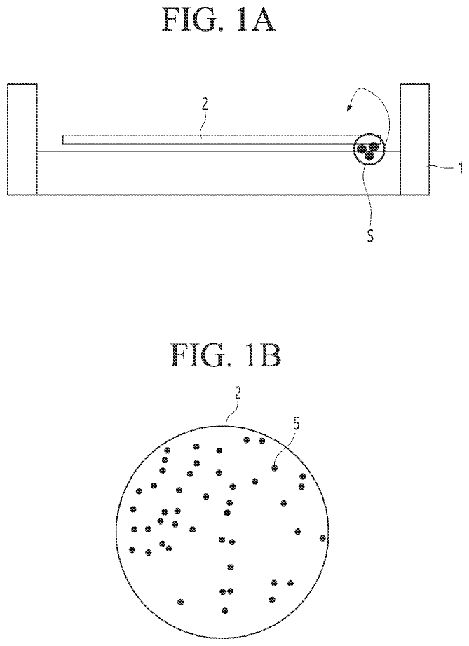

The sizes, shapes, dimensions, etc. of elements shown in the drawings can differ from actual ones. In addition, even if the same elements are shown in different sizes, shapes, dimensions, etc. between the drawings, this is only an example on the drawing, and the same elements have the same sizes, shapes, dimensions, etc. between the drawings.

### DETAILED DESCRIPTION OF EMBODIMENTS

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there can be directly on the other element or be other intermediate elements therebetween.

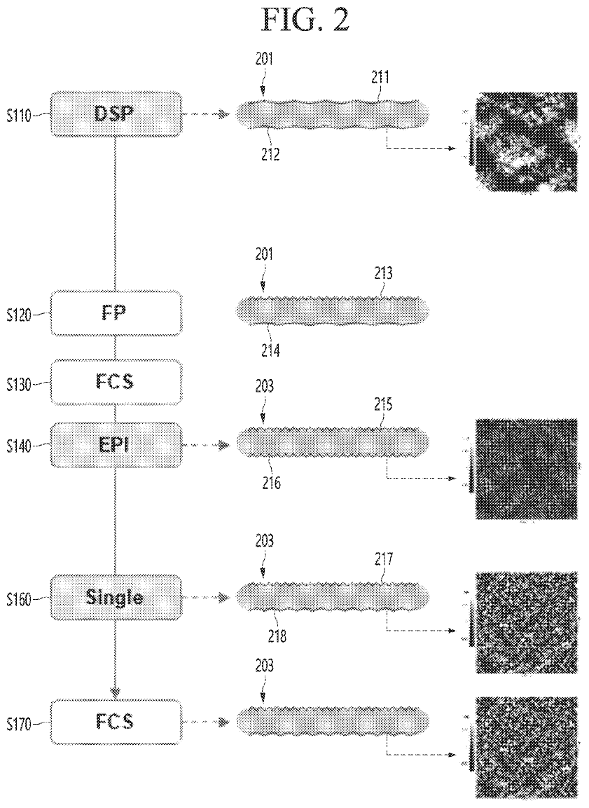

FIG. 2 illustrates a method for manufacturing an epitaxial wafer according to a comparative example.

As shown in FIG. 2, a double-side polishing process (hereinafter referred to as a DSP process) may be performed on the wafer 201 (S110). Prior to the DSP process (S110), a single crystal ingot can be obtained into a plurality of wafers 201 through a slicing process. For example, the slicing process may be performed using a wire. In this case, mechanical damage may occur on both surfaces of the wafer 201. This mechanical damage may be removed through the DSP process (S110).

The front and back surfaces of the wafer 201 on which the DSP process (S110) is performed may have a first roughness 211 and a second roughness 212, respectively. The second roughness 212 may be equal to or greater than the first roughness 211.

Next, the front surface of the wafer 201 can be polished using the final polishing (FP) process (S120). The roughness of the front surface of the wafer 201 can be reduced by the FP process (S120). In order to manufacture an epitaxial wafer 203 to be described later, the smaller the roughness of the front surface of the wafer 201, the better. To this end, only the front surface of the wafer 201 can be polished through the FP process (S120), thereby reducing the roughness of the front surface of the wafer 201.

The front and back surfaces of the wafer 201 on which the FP process (S120) is performed can have a third roughness 213 and a fourth roughness 214, respectively. The third roughness 213 can be smaller than the first roughness 211. For example, the third roughness 213 may be less than half of the first roughness 211. The fourth roughness 214 may be equal to the second roughness 212, but is not limited thereto.

Next, the wafer 201 may be cleaned using a final cleaning system (FCS) process (S130). HF, SC1 (Standard Clean-1, APM), SC2 (Standard Clean-2, HPM), etc. may be used as the cleaning solution. The FCS process (S130) may be omitted.

Next, an epitaxial layer (not shown) may be formed on the wafer 201 using an epitaxial (EPI) process (S140). The epitaxial layer may be formed of, for example, silicon comprising an n dopant, but is not limited thereto.

Meanwhile, the front and back surfaces of the epitaxial wafer 203 may have a fifth roughness 215 and a sixth roughness 216, respectively. Heat may be applied to perform the EPI process (S140) and a gas (hereinafter, referred to as an epi gas) for forming an epitaxial layer may be injected into the chamber. An epitaxial layer may be formed on the front surface of the wafer 201 using the epi gas, while the back surface of the wafer 201 may be etched by the epi gas so that the pattern of the surface of the back surface may be alleviated, thereby reducing the roughness, that is, the sixth roughness 216. For example, the fifth roughness 215 may be the same as the third roughness 213, but is not limited thereto. The sixth roughness 216 may be smaller than the fourth roughness 214. For example, the sixth roughness 216 may be less than half of the fourth roughness 214.

Subsequently, the back surface of the epitaxial wafer 203 may be cleaned using a single cleaning process (S160).

A precleansing system (PCS) process may be added before S160. The surface of the epitaxial layer may be cleaned using the PCS process.

The front and back surfaces of the epitaxial wafer 203 on which the single cleaning process (S160) is performed may have a seventh roughness 217 and an eighth roughness 218, respectively. The single cleaning process (S160) may clean only the back surface of the epitaxial wafer 203, and thus the roughness of the back surface of the epitaxial wafer 203, i.e., the eighth roughness 218, may increase. The seventh roughness 217 may be the same as the fifth roughness 215, but is not limited thereto. The eighth roughness 218 may be greater than the sixth roughness 216. For example, the eighth roughness 218 may be at least half that of the sixth roughness 216.

By increasing the eighth roughness 218 of the back surface of the epitaxial wafer 203 through the single cleaning process (S160), even if the epitaxial wafer 203 is placed on a stage for manufacturing a semiconductor device, slipping of the epitaxial wafer 203 is prevented, so that falling or damage to the epitaxial wafer (203) may be prevented, and contamination of the entire surface of the epitaxial wafer (203) by particles may be prevented.

Next, the epitaxial wafer 203 can be cleaned using the FCS process (S170). HF, SC1 (Standard Clean-1, APM), SC2 (Standard Clean-2, HPM), etc. can be used as the cleaning solution. The FCS process (S170) can be omitted.

However, there is a problem that in the comparative example, a single cleaning process (S160) is added to restore the sixth roughness 216 on the back surface of the epitaxial wafer 203 reduced by the EPI process (S140) to its original state, thereby complicating the process and increasing the cost.

In addition, even if the single cleaning process (S160) is added, there is no guarantee that the original roughness will be restored, and another problem may occur due to the addition of the single cleaning process (S160).

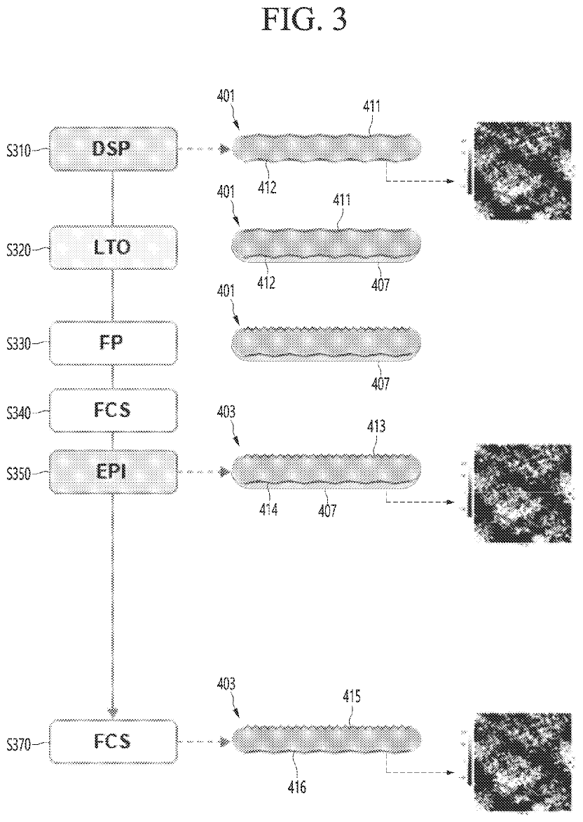

An embodiment for solving the above-described problem will be described with reference to FIGS. 3 to 6.

FIG. 3 illustrates a method for manufacturing an epitaxial wafer according to an embodiment.

In FIG. 3, the DSP process (S310), the FP process (S330), and the FCS process (S340) may be identical to S110, S120, and S130 illustrated in FIG. 2, respectively. In addition, in FIG. 3, the EPI process (S350) and the FCS process (S370) may be the same as S140 and S170 illustrated in FIG. 2.

In an embodiment, a low temperature oxidation (LTO) process may be performed (S320) between the DSP process (S310) and the FP process (S330). For example, a protective film 407 may be formed on the back surface of the wafer 401 using the LTO process (S320). For example, the protective film 407 may be an oxide film comprising SiOx, but is not limited thereto. For example, the protective film 407 is preferably formed thinly to facilitate later removal. For example, the protective film 407 may be 250 Å or less. Preferably, the protective film 407 may be 200 Å or less.

For example, the protective film 407 may be formed only on the back surface of the wafer 401. For example, the protective film 407 may be formed on the side surface as well as the back surface of the wafer 401.

For example, the protective film 407 may protect the back surface of the wafer 401 from subsequent processes, such as S330 to S350, so that the roughness of the back surface of the wafer 401 may be maintained as the roughness of the wafer 401 after the DSP process (S310). That is, the roughness of the back surface of the wafer 401 may be the same as the roughness of the wafer 401 after the DSP process (S310).

The LTO process (S320) may be performed, so that the protective film 407 may be formed on the back surface of the wafer 401. Accordingly, even if the FP process (S330), the FCS process (S340), the EPI process (S350), etc. are performed thereafter, the roughness of the back surface of the wafer 401 (or the epitaxial wafer 403) can be maintained to be the same as the roughness of the wafer 401 after the DSP process (S310) is performed by the protective film 407.

In summary, the front and back surfaces of the wafer 401 on which the DSP process (S310) is performed can have the first roughness 411 and the second roughness 412, respectively. The front and back surfaces of the epitaxial wafer 403 on which the EPI process (S350) is performed can have the third roughness 413 and the fourth roughness 414, respectively. The front and back surfaces of the epitaxial wafer 403 from which the protective film 407 is removed by the FCS process (S370) may have a fifth roughness 415 and a sixth roughness 416, respectively. For example, the second roughness 412 may be equal to or greater than the first roughness 411.

The third roughness 413 may be smaller than the first roughness 411. The fourth roughness 414 may be equal to the second roughness 412. Even if the EPI process (S350) is performed, the fourth roughness 414 on the back surface may remain unchanged due to the protective film 407, and the third roughness 413 on the front surface may become smaller than the first roughness 411.

In addition, the sixth roughness may be equal to the second roughness. Even if the protective film 407 is removed, the second roughness 412 of the back surface of the wafer 401 on which the DSP process (S310) is performed can be maintained as is. Accordingly, the sixth roughness 416 of the back surface of the epitaxial wafer 403 on which the protective film 407 is removed can be the same as the second roughness 412 of the back surface of the wafer 401 on which the DSP process (S310) is performed.

Meanwhile, the protective film 407 can be formed on the back surface of the wafer 401 using the LTO process (S320) before the FP process (S330) is performed. Therefore, the fourth roughness 414 of the back surface of the epitaxial wafer 403 on which the EPI process (S350) is performed by the protective film 407 can be maintained as is without being deformed. That is, the fourth roughness 414 of the back surface of the epitaxial wafer 403 on which the EPI process (S350) is performed may be the same as the second roughness 412 of the back surface of the wafer 401 on which the DSP process (S310) is performed. Therefore, even if the epitaxial wafer 403 is placed on a stage for manufacturing a semiconductor device, slipping of the epitaxial wafer 403 is prevented, so that not only falling or damage to the epitaxial wafer 403 can be prevented, but also contamination of the front surface of the epitaxial wafer 403 by particles can be prevented.

Meanwhile, in the embodiment, the protective film 407 may be removed through the FCS process (S370). For example, the protective film 407 may be etched by HF, etc. used in the FCS process. Even if the protective film 407 is removed using the FCS process (S370), the roughness of the back surface of the epitaxial wafer 403 on which the FCS process (S370) was performed may be the same as the second roughness 412 of the back surface of the wafer 401 on which the DSP process (S310) was performed.

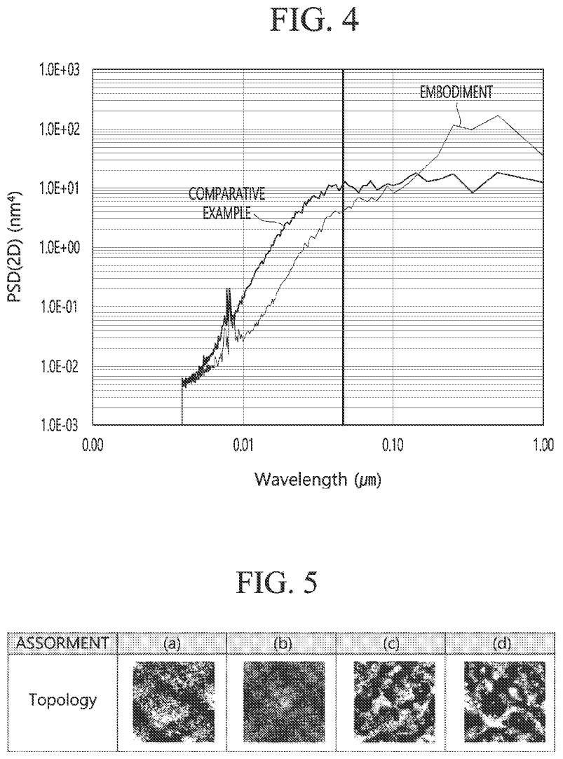

FIG. 4 is a power spectrum density (PSD) graph showing the roughness in each of the comparative example and the embodiment.

In FIG. 4, the comparative example is a case where the roughness of the back surface of the epitaxial wafer is formed using a single cleaning process, and the embodiment is a case where a protective film is formed on the back surface of the wafer using the LTO process and then the protective film is removed through the FCS process.

As shown in FIG. 4, when the comparative example and the embodiment are compared in the area below the reference line (see the thick vertical line in FIG. 4), the intensity of the comparative example is relatively strong, which means that there is a lot of fine roughness due to cleaning. In contrast, when the comparative example and the embodiment are compared in the area above the baseline, the intensity of the embodiment is relatively strong, which means that there is a lot of macro roughness due to polishing. Therefore, it can be seen that the roughness of the wafer surface of the embodiment comprises more macro roughness than that of the comparative example.

As shown in FIG. 2, when roughness is formed on the back surface of the epitaxial wafer using a single cleaning process like the comparative example, the roughness may comprise micro roughness. This micro roughness is smaller than the reference roughness required on the back surface of the epitaxial wafer, so that the epitaxial wafer may slide on the stage.

In contrast, as shown in FIG. 3, a protective film can be formed using the LTO process like the embodiment, and the protective film can be removed through the FCS process at least after the EPI process is performed. In this case, since the roughness of the back surface of the epitaxial wafer from which the protective film has been removed comprises a larger macro roughness than the reference roughness, slipping of the epitaxial wafer on the stage can be prevented.

FIG. 5 is a topology showing roughness according to comparative examples and embodiments.

FIG. 5(a) shows the roughness of the back surface of the wafer before the EPI process is performed, and FIG. 5(b) shows the roughness of the back surface of the epitaxial wafer as a comparative example when the protective film is not formed and the single cleaning process is not performed. FIG. 5(c) shows the roughness of the back surface of the epitaxial wafer as an example when a protective film of 230 Å is formed, and FIG. 5(d) shows the roughness of the back surface of the epitaxial wafer as an example when a

protective film of 260 Å is formed. As shown in FIG. 5(b), the roughness of the back surface of the epitaxial wafer in the comparative example is smaller than the roughness of the back surface of the wafer (FIG. 5(a)) before the EPI process is performed. The epitaxial wafer can slide on the stage.

In contrast, as shown in FIG. 5(c) or FIG. 5(d), the roughness of the back surface of the epitaxial wafer in the embodiment is 2 Å or more and similar to the roughness of the back surface of the wafer (FIG. 5(a)) before the EPI process is performed, so the epitaxial wafer does not slide on the stage.

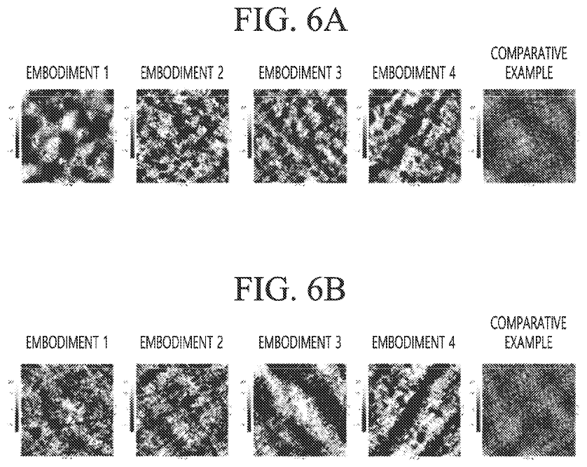

FIG. 6 (i.e., FIG. 6A and FIG. 6B) is a topology showing the roughness according to the position in each of the comparative example and the embodiment.

FIG. 6A shows the roughness of the back surface at a point 50 mm away from the center of the epitaxial wafer, and FIG. 6B shows the roughness of the back surface at a point 140 mm away from the center.

As shown in FIGS. 6A and 6B, it can be seen that the roughness of the back surface of the epitaxial wafers in each of the embodiment 1, the embodiment 2, the embodiment 3 and the embodiment 4 is much greater than the roughness of the back surface of the epitaxial wafer in the comparative example.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

What is claimed is:

1. A method for manufacturing an epitaxial wafer, comprising:
polishing front and back surfaces of a wafer using a double-side polishing process;
forming a protective film on the back surface of the polished wafer;
forming an epi layer on the front surface of the wafer on which the protective film is formed to form an epitaxial wafer; and
cleaning the epitaxial wafer.

2. The method of claim 1, wherein comprising:
forming the protective film on a side surface of the polished wafer.

3. The method of claim 1, wherein the front and back surfaces of the polished wafer have a first roughness and a second roughness, respectively, and
wherein the second roughness is equal to or greater than the first roughness.

4. The method of claim 1, wherein the front and back surfaces of the formed epitaxial wafer have a third roughness and a fourth roughness, respectively, and
wherein the third roughness is smaller than the first roughness, and the fourth roughness is equal to the second roughness.

5. The method of claim 1, wherein the cleaning of the epitaxial wafer comprises removing the protective film.

6. The method of claim 5, wherein the front and back surfaces of the epitaxial wafer from which the protective film has been removed have a fifth roughness and a sixth roughness, respectively, and
wherein the sixth roughness is equal to the second roughness.

7. The method of claim 1, wherein the protective film comprises an oxide film.

8. The method of claim 7, wherein the oxide film is formed using a low-temperature oxidation process.

9. The method of claim 1, wherein the protective film is 250 Å or less.

10. An epitaxial wafer manufactured according to claim 1.
